(19) United States
(12) Patent Application Publication
(10) Pub. No.: US 2025/0194122 A1
(43) Pub. Date: Jun. 12, 2025

(54) SEMICONDUCTOR STRUCTURE AND METHOD FOR MANUFACTURING THEREOF

(71) Applicant: ENKRIS SEMICONDUCTOR, INC., Suzhou (CN)

(72) Inventor: Kai CHENG, Suzhou (CN)

(73) Assignee: ENKRIS SEMICONDUCTOR, INC., Suzhou (CN)

(21) Appl. No.: 18/657,387

(22) Filed: May 7, 2024

(30) Foreign Application Priority Data
Dec. 7, 2023 (CN) 202311675693.X

(51) Int. Cl. H01L 29/66; H01L 29/47; H01L 29/872

(52) U.S. Cl. CPC H10D 8/051; H10D 8/60; H10D 64/64

(57) ABSTRACT

A semiconductor structure includes a substrate and a multi-channel heterojunction layer, and an anode and a cathode. The multi-channel heterojunction layer includes a first layer of heterojunction, . . . , a m^{th} layer of heterojunction, . . . , and a n^{th} layer of heterojunction; and the anode includes at least one set of anode fingers, any one set of anode fingers includes n anode fingers with different lengths, the n anode fingers include a first anode finger, . . . , a m^{th} anode finger, . . . , and a n^{th} anode finger, and the m^{th} anode finger partially penetrates the multi-channel heterojunction layer to the m^{th} layer of heterojunction. A plurality of channels of the semiconductor structure are controlled by a plurality of anode fingers, respectively, avoiding generation of an electric field peak, and further improving a breakdown voltage of the semiconductor structure.

### CROSS-REFERENCE TO RELATED APPLICATIONS

The present disclosure claims priority to Chinese Patent Application No. 202311675693.X, filed on Dec. 7, 2023, which is hereby incorporated by reference in its entirety.

### TECHNICAL FIELD

The present disclosure relates to the field of semiconductor technologies, in particular, to a semiconductor structure and a method for manufacturing thereof.

### BACKGROUND

A Junction Barrier Schottky (JBS) Diode as an enhancement mode Schottky diode has become a research hot issue. The outstanding advantages of the Junction Barrier Schottky Diode are on-state and fast switching characteristics of a Schottky Barrier Diode, and off-state and low leakage current characteristics of a PIN diode.

Compared with a Junction Barrier Schottky Diode with a single two-dimensional electron gas (2DEG) channel, a Junction Barrier Schottky with a plurality of 2DEG channel structures may have a relatively high electron mobility rate and a relatively low material sheet resistance, further reducing series resistance. However, in some cases, as for the Junction Barrier Schottky Diode with a plurality of 2DEG channel structures, a phenomenon of electric field concentration may occur at a Schottky interface formed by contact between an anode metal and a semiconductor, leading to generation of an electric field peak, and further leading to premature breakdown of devices.

### SUMMARY

In view of this, embodiments of the present disclosure provide a semiconductor structure and a method for manufacturing thereof, so as to solve technical problems of premature breakdown of devices due to electric field concentration occurred at an anode metal of a Junction Barrier Schottky Diode with a plurality of channels.

According to an aspect of the present disclosure, an embodiment of the present disclosure provides a semiconductor structure, including: a substrate and a multi-channel heterojunction layer which are stacked, the multi-channel heterojunction layer including a first layer of heterojunction, . . . , a m^{th} layer of heterojunction, . . . , and a n^{th} layer of heterojunction, which are disposed away from a direction of the substrate, where 1≤m≤n, n≥2, and both m and n are integers, and each layer of heterojunction of the multi-channel heterojunction layer including a channel layer and a barrier layer; and an anode and a cathode, wherein the anode is located at an end of the multi-channel heterojunction layer, and the cathode is located at another end of the multi-channel heterojunction layer; the anode includes at least one set of anode fingers, any one set of anode fingers of the at least one set of anode fingers includes n anode fingers with different lengths in a direction from the substrate to the multi-channel heterojunction layer, and the n anode fingers include a first anode finger, . . . , a m^{th} anode finger, . . . , and a n^{th} anode finger, where 1≤m≤n, n≥2, and both m and n are integers; and the m^{th} anode finger partially penetrates the multi-channel heterojunction layer to the m^{th} layer of heterojunction.

As an optional embodiment, a bottom surface of the m^{th} anode finger is located at any one of following positions in the m^{th} layer of heterojunction: in the channel layer, at an interface between the channel layer and the barrier layer, or in the barrier layer.

As an optional embodiment, along a direction perpendicular to the direction from the substrate to the multi-channel heterojunction layer, a width of the m^{th} anode finger is less than a width of the (m−1)^{th} anode finger, where 2≤m≤n, and both m and n are integers.

As an optional embodiment, the one set of anode fingers are electrically connected to each other.

As an optional embodiment, when the at least one set of anode fingers includes a plurality sets of anode fingers, a plurality of first anode fingers of the plurality sets of anode fingers are electrically connected to each other, . . . , a plurality of m^{th} anode fingers of the plurality sets of anode fingers are electrically connected to each other, . . . , and a plurality of n^{th} anode fingers of the plurality sets of anode fingers are electrically connected to each other.

As an optional embodiment, all anode fingers are electrically connected to each other.

As an optional embodiment, the semiconductor structure further includes: a plurality of first P-type regions disposed at intervals and located at an end of the multi-channel heterojunction layer, wherein each of the plurality of first P-type regions extends towards the substrate from a surface of a side, away from the substrate, of the multi-channel heterojunction layer, and a bottom surface of at least one of the plurality of first P-type regions is located in the channel layer of the first layer of heterojunction.

As an optional embodiment, at least one first P-type region is disposed between adjacent two sets of anode fingers.

As an optional embodiment, one first P-type region is disposed between each of at least two pairs of adjacent anode fingers of the one set of anode fingers.

As an optional embodiment, along a direction from the anode to the cathode, a length of each of the plurality of first P-type regions is uniformly increased or increased in a step-shape in a direction away from the substrate.

As an optional embodiment, along a direction from an anode finger to another anode finger, a length of each of the plurality of first P-type regions is uniformly increased or increased in a step-shape in a direction away from the substrate.

As an optional embodiment, the semiconductor structure further includes: a second P-type layer which is both located on the multi-channel heterojunction layer and the plurality of first P-type regions, wherein the second P-type layer is connected to the plurality of first P-type regions.

As an optional embodiment, along a direction from the anode to the cathode, a length of the second P-type layer is greater than or equal to a length of each of the plurality of first P-type regions.

According to another aspect of the present disclosure, an embodiment of the present disclosure provides a method for manufacturing a semiconductor structure, including: growing a multi-channel heterojunction layer on a substrate, the multi-channel heterojunction layer including a first layer of heterojunction, . . . , a m^{th} layer of heterojunction, . . . , and a n^{th} layer of heterojunction, which are disposed in a direction away from the substrate, where 1≤m≤n, n≥2, and both m and n are integers, and each layer of heterojunction of the multi-channel heterojunction layer including a channel layer and a barrier layer; etching an end of the multi-channel heterojunction layer to form an anode region, and etching another end of the multi-channel heterojunction layer to form a cathode region, the anode region including at least one set of anode finger grooves, any one set of anode finger grooves of the at least one set of anode finger grooves including a first anode finger groove, . . . , a m^{th} anode finger groove, . . . , and a n^{th} anode finger groove with different lengths in a direction from the substrate to the multi-channel heterojunction layer, where 1≤m≤n, n≥2, and both m and n are integers; and the m^{th} anode finger groove partially penetrating the multi-channel heterojunction layer to the m^{th} layer of heterojunction; and disposing an anode in the anode region, and disposing a cathode in the cathode region, a first anode finger, . . . , a m^{th} anode finger, . . . , and a n^{th} anode finger being disposed in the first anode finger groove, . . . , the m^{th} anode finger groove, . . . , and the n^{th} anode finger groove, respectively, and the m^{th} anode finger partially penetrating the multi-channel heterojunction layer to the m^{th} layer of heterojunction.

As an optional embodiment, a bottom surface of the m^{th} anode finger groove is located in any one of following positions in the m^{th} layer of heterojunction: in the channel layer, at an interface between the channel layer and the barrier layer, or in the barrier layer.

As an optional embodiment, along a direction perpendicular to the direction from the substrate to the multi-channel heterojunction layer, a width of the m^{th} anode finger groove is less than a width of the (m−1)^{th} anode finger groove, where 2≤m≤n, and both m and n are integers.

As an optional embodiment, the method for manufacturing the semiconductor structure further includes: disposing a plurality of first P-type regions at intervals located at an end of the multi-channel heterojunction layer, each of the plurality of first P-type regions extending towards the substrate from a surface of a side, away from the substrate, of the multi-channel heterojunction layer, and a bottom surface of at least one of the plurality of first P-type regions being located in the channel layer of the first layer of heterojunction.

As an optional embodiment, the method for manufacturing the semiconductor structure further includes: continuing to epitaxially form a healed second P-type layer on the plurality of first P-type regions.

### BRIEF DESCRIPTION OF THE DRAWINGS

FIG. 1 is a schematic structural diagram of a semiconductor structure according to an embodiment of the present disclosure.

FIG. 2a to FIG. 2c are side views of semiconductor structures according to embodiments of the present disclosure.

FIG. 3 is a side view of a semiconductor structure according to an embodiment of the present disclosure.

FIG. 4a and FIG. 4b are side views of semiconductor structures according to embodiments of the present disclosure.

FIG. 5 is a schematic structural diagram of a semiconductor structure according to an embodiment of the present disclosure.

FIG. 6a and FIG. 6b are side views of semiconductor structures according to embodiments of the present disclosure.

FIG. 7a and FIG. 7b are cross-sectional diagrams of a first P-type region of a semiconductor structure according to an embodiment of the present disclosure.

FIG. 8a and FIG. 8b are side views of semiconductor structures according to an embodiment of the present disclosure.

FIG. 9 is a schematic structural diagram of a semiconductor structure according to an embodiment of the present disclosure.

FIG. 10 is a schematic flowchart of a method for manufacturing a semiconductor structure according to an embodiment of the present disclosure.

FIG. 11 to FIG. 18 are schematic structural diagrams of intermediate structures in a manufacturing process of a semiconductor structure according to an embodiment of the present disclosure.

### DETAILED DESCRIPTION OF THE EMBODIMENTS

The following clearly and completely describes technical solutions in the embodiments of the present disclosure with reference to the accompanying drawings in the embodiments of the present disclosure. Apparently, the described embodiments are a part rather than all of the embodiments of the present disclosure. All other embodiments obtained by a person skilled in the art based on the embodiments of the present disclosure without creative efforts shall fall within the protection scope of the present disclosure.

In related technologies, a phenomenon of electric field concentration may occur at a Schottky interface formed by contact between an anode metal and a semiconductor when a Junction Barrier Schottky Diode with a plurality of 2DEG channel structures is subjected to a large reverse bias voltage, leading to generation of an electric field peak, and further leading to premature breakdown of devices.

In order to solve technical problems of premature breakdown of devices due to electric field concentration occurred at an anode metal of a Junction Barrier Schottky Diode with a plurality of channels, the present disclosure provides a semiconductor structure and a method for manufacturing thereof, the semiconductor structure includes a substrate and a multi-channel heterojunction layer which are stacked, and an anode and a cathode, the anode is located at an end of the multi-channel heterojunction layer, and the cathode is located at another end of the multi-channel heterojunction layer. The multi-channel heterojunction layer includes a first layer of heterojunction, . . . , a m^{th} layer of heterojunction, . . . , and a n^{th} layer of heterojunction, which are disposed away from a direction of the substrate, and each layer of heterojunction of the multi-channel heterojunction layer includes a channel layer and a barrier layer; and the anode includes at least one set of anode fingers, any one set of anode fingers includes n anode fingers with different lengths in a direction from the substrate to the multi-channel heterojunction layer, the n anode fingers include a first anode finger, . . . , a m^{th} anode finger, . . . , and a n^{th} anode finger, and the m^{th} anode finger partially penetrates the multi-channel heterojunction layer to the m^{th} layer of heterojunction. In the present disclosure, a plurality of channels of the semiconductor structure are controlled by a plurality of anode fingers, respectively, which avoids a phenomenon of electric field concentration occurred at a Schottky interface formed by contact between an anode metal and a semiconductor when a semiconductor structure is subjected to a large reverse bias voltage, thereby avoiding generation of an electric field peak, and further improving a breakdown voltage of the semiconductor structure. The plurality of anode fingers designed by the present disclosure are located at a same side of the multi-channel heterojunction layer, and therefore, when the plurality of anode fingers for independent control of a plurality of channels are formed, there is no need to etch any steps, i.e., there is no need to sacrifice a length of the channel, so that independent control of the plurality of channels is achieved, while effectively reducing a space occupied by an anode region.

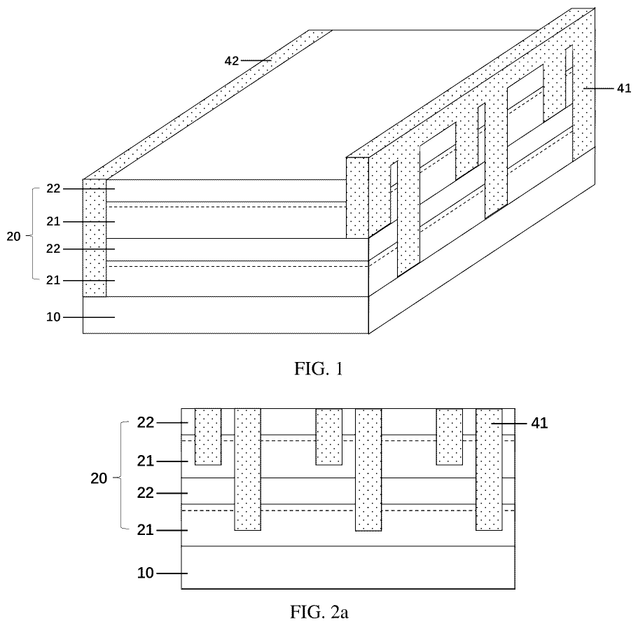

The following further illustrates a semiconductor structure and a method for manufacturing thereof provided by the present disclosure with reference of FIG. 1 to FIG. 18.

FIG. 1 is a schematic structural diagram of a semiconductor structure according to an embodiment of the present disclosure. As shown in FIG. 1, the semiconductor structure includes a substrate 10 and a multi-channel heterojunction layer 20 which are stacked, and an anode 41 and a cathode 42, the anode 41 is located at an end of the multi-channel heterojunction layer 20, and the cathode 42 is located at another end of the multi-channel heterojunction layer 20. The multi-channel heterojunction layer 20 includes a first layer of heterojunction, . . . , a m^{th} layer of heterojunction, . . . , and a n^{th} layer of heterojunction, which are disposed away from a direction of the substrate 10, where 1≤m≤n, n≥2, and both m and n are integers, and each layer of heterojunction of the multi-channel heterojunction layer 20 includes a channel layer 21 and a barrier layer 22; and the anode 41 includes at least one set of anode fingers, any one set of anode fingers includes n anode fingers with different lengths in a direction from the substrate 10 to the multi-channel heterojunction layer 20, the n anode fingers include a first anode finger, . . . , a m^{th} anode finger, . . . , and a n^{th} anode finger, where 1≤m≤n, n≥2, and both m and n are integers, and the m^{th} anode finger partially penetrates the multi-channel heterojunction layer 20 to the m^{th} layer of heterojunction.

In this embodiment, the multi-channel heterojunction layer 20 may only include two layers of heterojunction, i.e., a first layer of heterojunction and a second layer of heterojunction which are stacked in the direction away from the substrate 10. In other embodiments, the multi-channel heterojunction layer 20 may include three layers of heterojunction or more layers of heterojunction, i.e., a first layer of heterojunction, a second layer of heterojunction, . . . , and a n^{th} layer of heterojunction, where n≥3. Each layer of heterojunction includes the channel layer 21 and the barrier layer 22, and a band gap of a material of the barrier layer 22 is greater than a band gap of a material of the channel layer 21. The materials of the channel layer 21 and the barrier layer 22 may include group III nitride materials, and a two-dimensional electron gas may be formed at an interface between the channel layer 21 and the barrier layer 22. In an optional solution, the channel layer 21 is a GaN layer, and the barrier layer 22 is an AlGaN layer. In other optional solutions, a material combination of the channel layer 21 and the barrier layer 22 may also be GaN/AlN, GaN/InN, GaN/InAlGaN, GaAs/AlGaAs, GaN/InAlN or InN/InAlN. Materials of multi-layer of heterojunction may be the same or different, which is not limited specifically in the present disclosure.

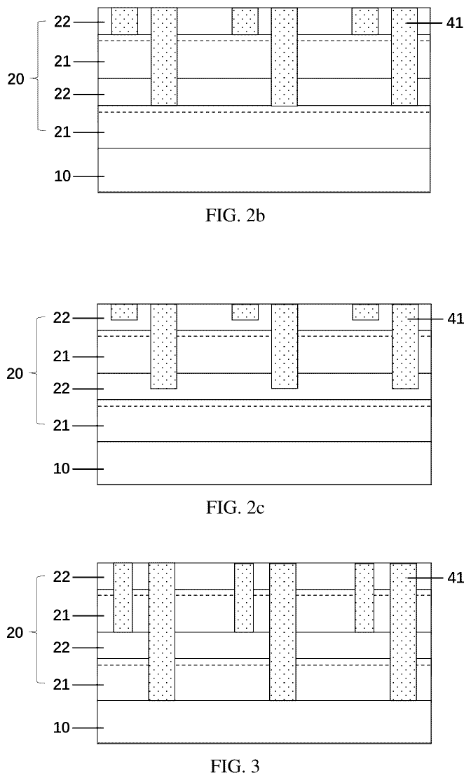

FIG. 2a to FIG. 2c are side views of semiconductor structures according to embodiments of the present disclosure. In this embodiment, the m^{th} anode finger partially penetrates the multi-channel heterojunction layer 20 to the m^{th} layer of heterojunction, a bottom surface of the m^{th} anode finger is located at any one of following positions in the m^{th} layer of heterojunction: in the channel layer 21 (shown in FIG. 2a), at an interface between the channel layer 21 and the barrier layer 22 (shown in FIG. 2b), or in the barrier layer 22 (shown in FIG. 2c). The anode fingers are located at different depths of the multi-channel heterojunction layer 20, so that a control capability of different anode fingers on corresponding channels may be regulated.

FIG. 3 is a side view of a semiconductor structure according to an embodiment of the present disclosure. In this embodiment, along a direction perpendicular to the direction from the substrate 10 to the multi-channel heterojunction layer 20, a width of the m^{th} anode finger is less than a width of the (m−1)^{th} anode finger, where 2≤m≤n, and both m and n are integers, i.e., the farther a layer of heterojunction away from the substrate 10 is, the less of a width of the anode finger corresponding to the layer of heterojunction is. The larger the width of the anode finger is, the greater the control capability provided by the anode finger is, and under a condition of the same width of the anode fingers, an anode finger corresponding to a layer of heterojunction away from the substrate 10 has greater control capability on the layer of heterojunction, and therefore, the width of the anode finger corresponding to the layer of heterojunction away from the substrate 10 may be reduced, so as to reduce the use of anode materials.

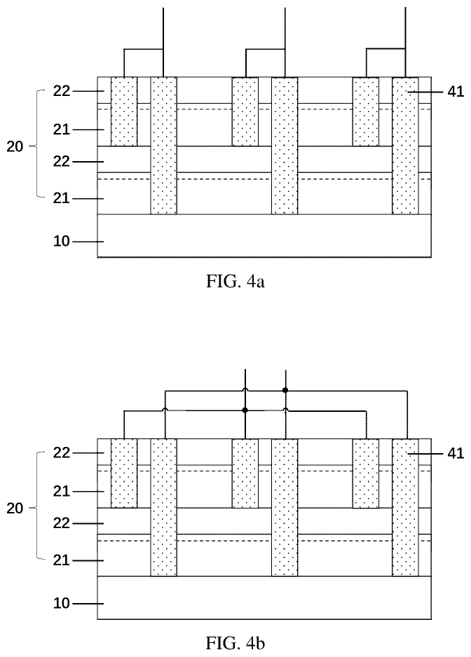

FIG. 4a and FIG. 4b are side views of semiconductor structures according to embodiments of the present disclosure. In this embodiment, all anode fingers are electrically connected to each other (shown in FIG. 1). In an embodiment, one set of anode fingers are electrically connected to each other, and different sets of anode fingers are not electrically connected to each other (shown in FIG. 4a). In another embodiment, when the at least one set of anode fingers includes a plurality sets of anode fingers, a plurality of first anode fingers of the plurality sets of anode fingers are electrically connected to each other, . . . , a plurality of m^{th} anode fingers of the plurality sets of anode fingers are electrically connected to each other, . . . , a plurality of n^{th} anode fingers of the plurality sets of anode fingers are electrically connected to each other. Disposal of different electrical connection modes of the anode fingers may achieve joint or independent control for different channels of the semiconductor structure.

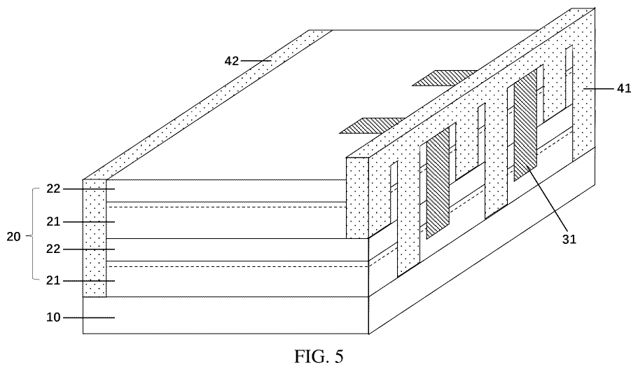

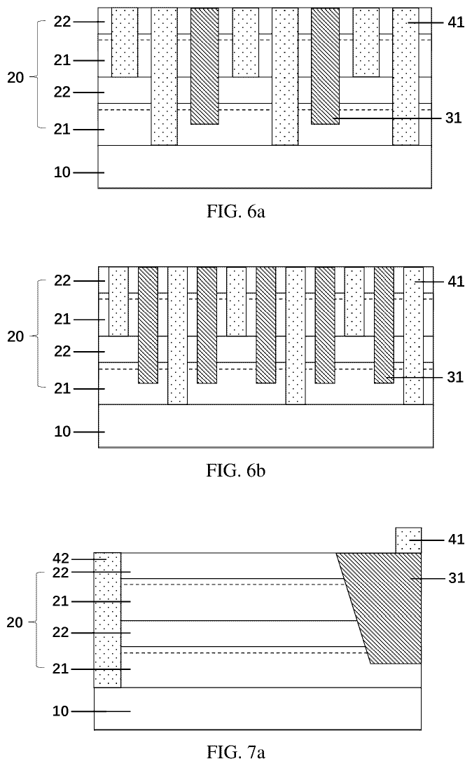

FIG. 5 is a schematic structural diagram of a semiconductor structure according to an embodiment of the present disclosure. FIG. 6a and FIG. 6b are side views of semiconductor structures according to embodiments of the present disclosure. In an embodiment, as shown in FIG. 5, the semiconductor structure further includes: a plurality of first P-type regions 31 disposed at intervals and located at an end of the multi-channel heterojunction layer 20, each of the plurality of first P-type regions 31 extends towards the substrate 10 from a surface of a side, away from the substrate 10, of the multi-channel heterojunction layer 20, and a bottom surface of at least one of the plurality of first P-type regions 31 is located in the channel layer 21 of the first layer of heterojunction. As shown in FIG. 6a, at least one first P-type region 31 is disposed between adjacent two sets of anode fingers; and as shown in FIG. 6b, one first P-type region 31 is disposed between each of at least two pairs of adjacent anode fingers of the one set of anode fingers. A transverse PN junction is formed by the first P-type region 31 and a two-dimensional electron gas in a heterojunction, so that during a reverse bias, a depletion region of the PN junction broadens to cut off a current channel, effectively shielding a Schottky junction with a low barrier height to restrain a Schottky barrier lowering effect and to control a reverse leakage current, and further improving a breakdown voltage and keeping a relatively low threshold voltage. The multi-layer of heterojunction are stacked between the anode 41 and the cathode 42, so that a plurality of two-dimensional electron gas passages connected in parallel are formed, compensating for depletion of the two-dimensional electron gas by the first P-type region 31, and further ensuring a forward current of a diode.

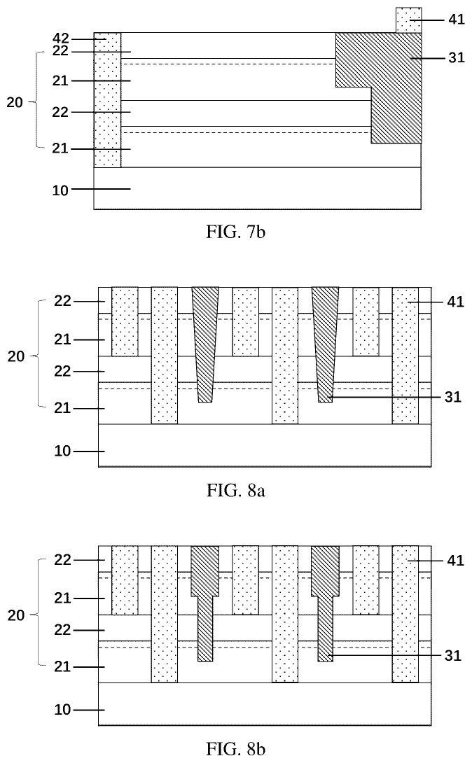

FIG. 7a and FIG. 7b are cross-sectional diagrams of first P-type regions of semiconductor structures according to embodiments of the present disclosure. FIG. 8a and FIG. 8b are side views of semiconductor structures according to embodiments of the present disclosure. In an embodiment, there is a two-dimensional electron gas at a contact interface between the channel layer 21 and the barrier layer 22 in each layer of heterojunction, a size relationship of the first P-type regions 31 at different positions of the two-dimensional electron gases includes at least one of following relationships: the first P-type regions 31 having different lengths along a direction from the anode 41 to the cathode 42, or the first P-type regions 31 having different lengths along a direction from an anode finger to another anode finger. For example, a size of each first P-type region 31 includes at least one of followings: along the direction from the anode 41 to the cathode 42, a length of each first P-type region 31 being uniformly increased (shown in FIG. 7a) or increased in a step-shape (shown in FIG. 7b) in a direction away from the substrate 10, or along a direction from an anode finger to another anode finger, a length of each first P-type region 31 being uniformly increased (shown in FIG. 8a) or increased in a step-shape (shown in FIG. 8b) in a direction away from the substrate 10. The length of the first P-type region 31 is changed, so that on one hand, a shape of a channel may be changed to increase an electronic mobility path, reducing an on resistance; on the other hand, a width of a depletion layer may be changed to reduce a peak electric field, increasing a breakdown voltage.

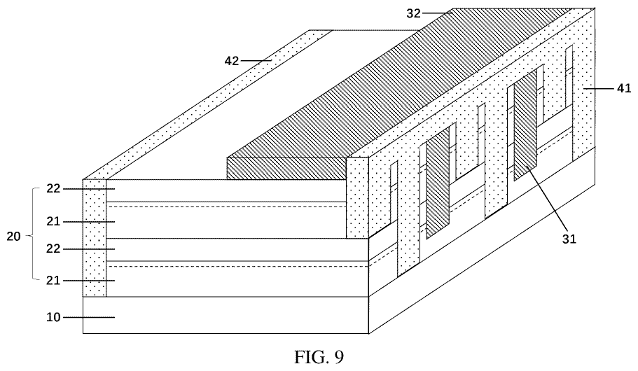

FIG. 9 is a schematic structural diagram of a semiconductor structure according to an embodiment of the present disclosure. In an embodiment, as shown in FIG. 9, a P-type epitaxial layer further includes a second P-type layer 32 which is both located on the multi-channel heterojunction layer 20 and the plurality of first P-type regions 31, and the second P-type layer 32 is connected to the plurality of first P-type regions 31. Along the direction from the anode 41 to the cathode 42, a length of the second P-type layer 32 is greater than or equal to a length of the first P-type region 31. The first P-type region 31 and the second P-type layer 32 can work synergistically, so that an electric field on a surface of a heterojunction structure between the anode 41 and the cathode 42 may be redistributed to improve electric field distribution at an edge of the anode 41, preventing avalanche breakdown, and further improving a breakdown voltage of devices and reducing a reverse leakage current.

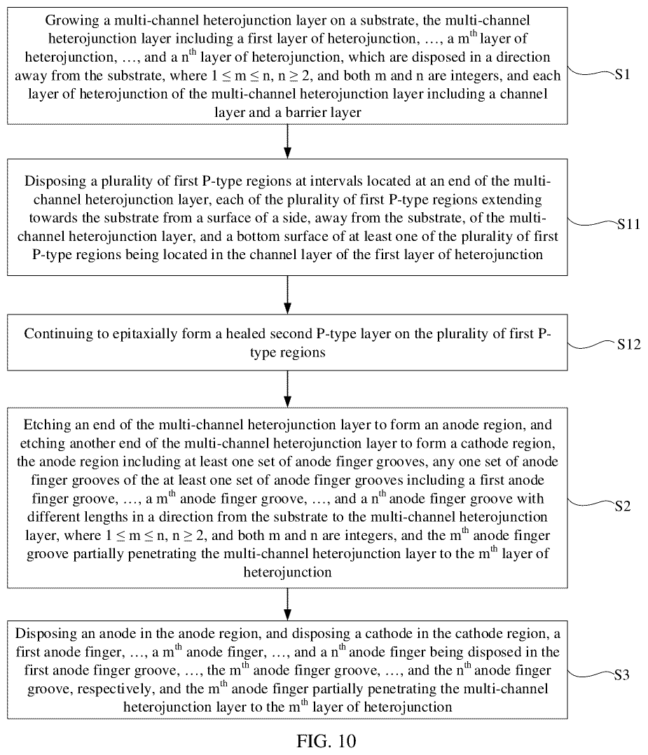

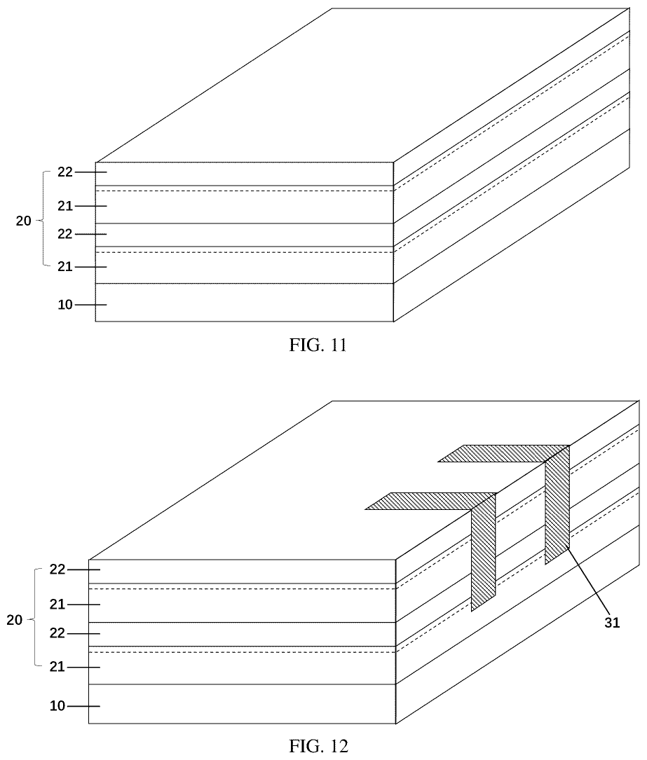

According to another aspect of the present disclosure, FIG. 10 is a schematic flowchart of a method for manufacturing a semiconductor structure according to an embodiment of the present disclosure, and FIG. 11 to FIG. 18 are schematic structural diagrams of intermediate structures in a manufacturing process of a semiconductor structure according to an embodiment of the present disclosure. As shown in FIG. 10, a method for manufacturing a semiconductor structure according to an embodiment of the present disclosure includes following steps.

Step S1: growing a multi-channel heterojunction layer on a substrate, the multi-channel heterojunction layer including a first layer of heterojunction, . . . , a m^{th} layer of heterojunction, . . . , and a n^{th} layer of heterojunction, which are disposed in a direction away from the substrate, where 1≤m≤n, n≥2, and both m and n are integers, and each layer of heterojunction of the multi-channel heterojunction layer including a channel layer and a barrier layer.

As shown in FIG. 11, the multi-channel heterojunction layer 20 is grown on the substrate 10, the multi-channel heterojunction layer 20 includes the first layer of heterojunction, . . . , the m^{th} layer of heterojunction, . . . , and the n^{th} layer of heterojunction, which are disposed in the direction away from the substrate 10, where 1≤m≤n, n≥2, and both m and n are integers, and each layer of heterojunction includes the channel layer 21 and the barrier layer 22. A material of the substrate 10 includes any one or a combination of Si, Al₂O₃, GaN, SiC or AlN. The method for growing the multi-channel heterojunction layer 20 on the substrate 10 may be in situ or achieved by Atom Layer Deposition (ALD), Chemical Vapor Deposition (CVD), Molecular Beam Epitaxy (MBE), Plasma Enhanced Chemical Vapor Deposition (PECVD), Low Pressure Chemical Vapor Deposition (LPCVD), Metal-Organic Chemical Vapor Deposition (MOCVD) or a combination thereof.

After the Step S1, the method for manufacturing the semiconductor structure further includes Step S11: disposing a plurality of first P-type regions at intervals located at an end of the multi-channel heterojunction layer, each of the plurality of first P-type regions extending towards the substrate from a surface of a side, away from the substrate, of the multi-channel heterojunction layer, and a bottom surface of at least one of the plurality of first P-type regions being located in the channel layer of the first layer of heterojunction.

As shown in FIG. 12, the plurality of first P-type regions 31 are disposed at intervals and located at an end of the multi-channel heterojunction layer 20, each first P-type region 31 extends towards the substrate 10 from the surface of the side, away from the substrate 10, of the multi-channel heterojunction layer 20, and the bottom surface of the at least one first P-type region 31 is located in the channel layer 21 of the first layer of heterojunction. A transverse PN junction is formed by the first P-type region 31 and a two-dimensional electron gas in a heterojunction, so that during a reverse bias, a depletion region of the PN junction broadens to cut off a current channel, effectively shielding a Schottky junction with a low barrier height to restrain a Schottky barrier lowering effect and to control a reverse leakage current, and further improving breakdown voltage and keeping a relatively low threshold voltage.

After the Step S11, the method for manufacturing the semiconductor structure further includes Step S12: continuing to epitaxially form a healed second P-type layer on the plurality of first P-type regions.

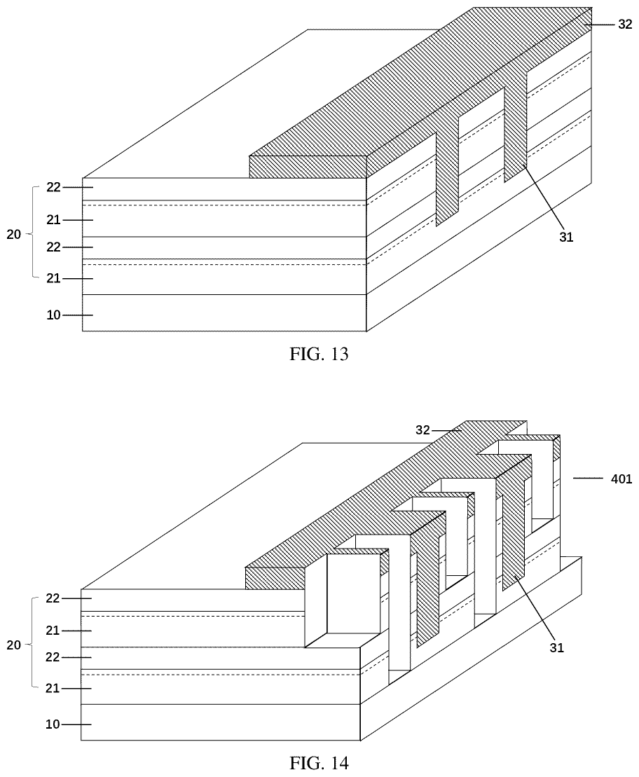

As shown in FIG. 13, the healed second P-type layer 32 is continued to epitaxially form on the plurality of first P-type regions 31. The plurality of first P-type regions 31 and the second P-type layer 32 can work synergistically, so that an electric field on a surface of a heterojunction structure between the anode 41 and the cathode 42 may be redistributed to improve electric field distribution at an edge of the anode 41, preventing avalanche breakdown, and further improving a breakdown voltage of devices and reducing a reverse leakage current.

Step S2: etching an end of the multi-channel heterojunction layer to form an anode region, and etching another end of the multi-channel heterojunction layer to form a cathode region, the anode region including at least one set of anode finger grooves, any one set of anode finger grooves of the at least one set of anode finger grooves including a first anode finger groove, . . . , a m^{th} anode finger groove, . . . , and a n^{th} anode finger groove with different lengths in a direction from the substrate to the multi-channel heterojunction layer, where 1≤m≤n, n≥2, and both m and n are integers, and the m^{th} anode finger groove partially penetrating the multi-channel heterojunction layer to the m^{th} layer of heterojunction.

As shown in FIG. 14, an end of the multi-channel heterojunction layer is etched to form the anode region, another end of the multi-channel heterojunction layer is etched to form the cathode region, the anode region includes the at least one set of anode finger grooves 401, any one set of anode finger grooves 401 of the at least one set of anode finger grooves 401 includes the first anode finger groove 401, . . . , the m^{th} anode finger groove 401, . . . , and the n^{th} anode finger groove 401 with different lengths, where 1≤m≤n, n≥2, and both m and n are integers, and the m^{th} anode finger groove 401 partially penetrates the multi-channel heterojunction layer 20 to the m^{th} layer of heterojunction.

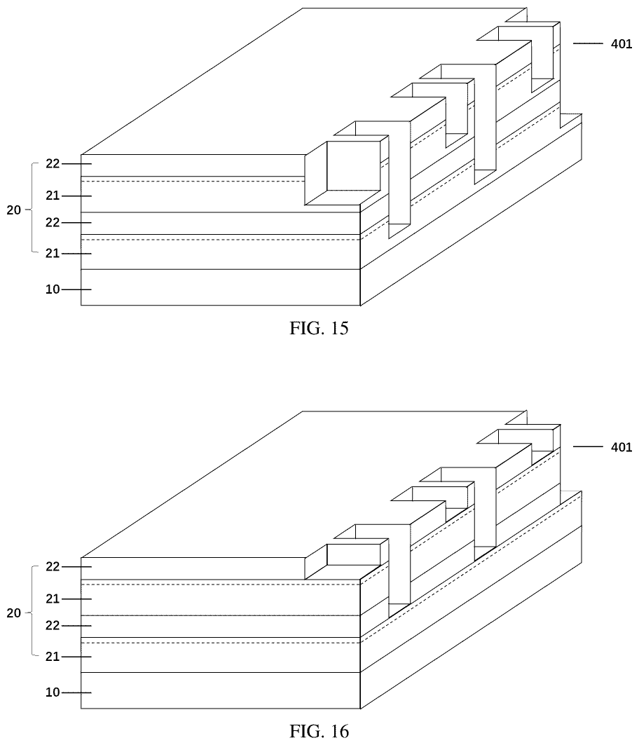

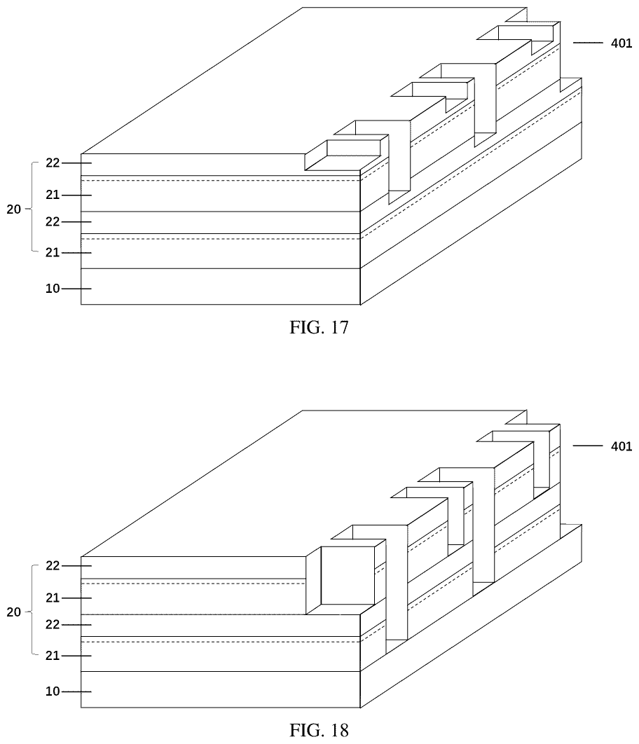

In an embodiment, a bottom surface of the m^{th} anode finger groove 401 is located in any one of following positions in the m^{th} layer of heterojunction: in the channel layer 21 (shown in FIG. 15), at an interface between the channel layer 21 and the barrier layer 22 (shown in FIG. 16), or in the barrier layer 22 (shown in FIG. 17). The anode fingers are located at different depths of the multi-channel heterojunction layer 20, so that a control capability of different anode fingers on corresponding channels may be regulated.

In an embodiment, as shown in FIG. 18, along a direction perpendicular to the direction from the substrate 10 to the multi-channel heterojunction layer 20, a width of the m^{th} anode finger groove 401 is less than a width of the (m−1)^{th} anode finger groove 401, where 2≤m≤n, and both m and n are integers.

Step S3, disposing an anode in the anode region, and disposing a cathode in the cathode region, a first anode finger, . . . , a m^{th} anode finger, . . . , and a n^{th} anode finger being disposed in the first anode finger groove, . . . , the m^{th} anode finger groove, . . . , and the n^{th} anode finger groove, respectively, and the m^{th} anode finger partially penetrating the multi-channel heterojunction layer to the m^{th} layer of heterojunction.

As shown in FIG. 14, the anode 41 is disposed in the anode region, the cathode 42 is disposed in the cathode region, the first anode finger, . . . , the m^{th} anode finger, . . . , and the n^{th} anode finger are disposed in the first anode finger groove, . . . , the m^{th} anode finger groove, . . . , and the n^{th} anode finger groove, respectively, and the m^{th} anode finger partially penetrates the multi-channel heterojunction layer 20 to the m^{th} layer of heterojunction, so as to form the semiconductor structure shown in FIG. 9.

The present disclosure provides a semiconductor structure and a method for manufacturing thereof, the semiconductor structure includes a substrate and a multi-channel heterojunction layer which are stacked, and an anode and a cathode, the anode is located at an end of the multi-channel heterojunction layer, and the cathode is located at another end of the multi-channel heterojunction layer. The multi-channel heterojunction layer includes a first layer of heterojunction, . . . , a m^{th} layer of heterojunction, . . . , and a n^{th} layer of heterojunction, which are disposed away from a direction of the substrate, and each layer of heterojunction of the multi-channel heterojunction layer includes a channel layer and a barrier layer; and the anode includes at least one set of anode fingers, any one set of anode fingers includes n anode fingers with different lengths in a direction from the substrate to the multi-channel heterojunction layer, the n anode fingers include a first anode finger, . . . , a m^{th} anode finger, . . . , and a n^{th} anode finger, and the m^{th} anode finger partially penetrates the multi-channel heterojunction layer to the m^{th} layer of heterojunction. In the present disclosure, a plurality of channels of the semiconductor structure are controlled by a plurality of anode fingers, respectively, which avoids a phenomenon of electric field concentration occurred at a Schottky interface formed by contact between an anode metal and a semiconductor when a semiconductor structure is subjected to a large reverse bias voltage, avoiding generation of an electric field peak, and further improving a breakdown voltage of the semiconductor structure. The plurality of anode fingers designed by the present disclosure are located at a same side of the multi-channel heterojunction layer, and therefore, when the plurality of anode fingers for independent control of a plurality of channels are formed, there is no need to etch any steps, i.e., there is no need to sacrifice a length of the channel, so that independent control of the plurality of channels is achieved, while effectively reducing a space occupied by an anode region.

It should be understood that the terms “including” and variations thereof used in the present disclosure are open ended, i.e., “including but not limited to”. The term “an embodiment” means “at least one embodiment”, and the term “another embodiment” means “at least one further embodiment”. In this specification, schematic representation of the above terms does not necessarily refer to the same embodiment or example. Furthermore, specific features, structures, materials, or characteristics described may be combined in any suitable manner in any one or more embodiments or examples. In addition, in case of no contradiction, a person skilled in the art may combine and integrate different embodiments or examples described in this specification, as well as features of different embodiments or examples.

The above are only preferred embodiments of the present disclosure, and are not intended to limit the present disclosure. Any modification, equivalent replacement, etc. made within the spirit and principle of the present disclosure shall be included within the protection scope of the present disclosure. cm What is claimed is:

1. A semiconductor structure, comprising:
a substrate and a multi-channel heterojunction layer which are stacked, the multi-channel heterojunction layer comprising a first layer of heterojunction, . . . , a m^{th} layer of heterojunction, . . . , and a n^{th} layer of heterojunction, which are disposed away from a direction of the substrate, where 1≤m≤n, n≥2, and both m and n are integers, and each layer of heterojunction of the multi-channel heterojunction layer comprising a channel layer and a barrier layer; and
an anode and a cathode, wherein the anode is located at an end of the multi-channel heterojunction layer, and the cathode is located at another end of the multi-channel heterojunction layer; the anode comprises at least one set of anode fingers, any one set of anode fingers of the at least one set of anode fingers comprises n anode fingers with different lengths in a direction from the substrate to the multi-channel heterojunction layer, and the n anode fingers comprise a first anode finger, . . . , a m^{th} anode finger, . . . , and a n^{th} anode finger, where 1≤m≤n, n≥2, and both m and n are integers; and the m^{th} anode finger partially penetrates the multi-channel heterojunction layer to the m^{th} layer of heterojunction.

2. The semiconductor structure according to claim 1, wherein a bottom surface of the m^{th} anode finger is located at any one of following positions in the m^{th} layer of heterojunction: in the channel layer, at an interface between the channel layer and the barrier layer, or in the barrier layer.

3. The semiconductor structure according to claim 1, wherein along a direction perpendicular to the direction from the substrate to the multi-channel heterojunction layer, a width of the m^{th} anode finger is less than a width of the (m−1)^{th} anode finger, where 2≤m≤n, and both m and n are integers.

4. The semiconductor structure according to claim 1, wherein the one set of anode fingers are electrically connected to each other.

5. The semiconductor structure according to claim 1, wherein when the at least one set of anode fingers comprises a plurality sets of anode fingers, a plurality of first anode fingers of the plurality sets of anode fingers are electrically connected to each other, . . . , a plurality of m^{th} anode fingers of the plurality sets of anode fingers are electrically connected to each other, . . . , and a plurality of n^{th} anode fingers of the plurality sets of anode fingers are electrically connected to each other.

6. The semiconductor structure according to claim 1, wherein all anode fingers are electrically connected to each other.

7. The semiconductor structure according to claim 1, further comprising:
a plurality of first P-type regions disposed at intervals and located at an end of the multi-channel heterojunction layer, wherein each of the plurality of first P-type regions extends towards the substrate from a surface of a side, away from the substrate, of the multi-channel heterojunction layer, and a bottom surface of at least one of the plurality of first P-type regions is located in the channel layer of the first layer of heterojunction.

8. The semiconductor structure according to claim 7, wherein at least one first P-type region is disposed between adjacent two sets of anode fingers.

9. The semiconductor structure according to claim 7, wherein one first P-type region is disposed between each of at least two pairs of adjacent anode fingers of the one set of anode fingers.

10. The semiconductor structure according to claim 7, wherein along a direction from the anode to the cathode, a length of each of the plurality of first P-type regions is uniformly increased or increased in a step-shape in a direction away from the substrate.

11. The semiconductor structure according to claim 7, wherein along a direction from an anode finger to another anode finger, a length of each of the plurality of first P-type regions is uniformly increased or increased in a step-shape in a direction away from the substrate.

12. The semiconductor structure according to claim 7, further comprising a second P-type layer which is both located on the multi-channel heterojunction layer and the plurality of first P-type regions, wherein the second P-type layer is connected to the plurality of first P-type regions.

13. The semiconductor structure according to claim 12, wherein along a direction from the anode to the cathode, a length of the second P-type layer is greater than or equal to a length of each of the plurality of first P-type regions.

14. A method for manufacturing a semiconductor structure, comprising:
growing a multi-channel heterojunction layer on a substrate, the multi-channel heterojunction layer comprising a first layer of heterojunction, . . . , a m^{th} layer of heterojunction, . . . , and a n^{th} layer of heterojunction, which are disposed in a direction away from the substrate, where 1≤m≤n, n≥2, and both m and n are integers, and each layer of heterojunction of the multi-channel heterojunction layer comprising a channel layer and a barrier layer;
etching an end of the multi-channel heterojunction layer to form an anode region, and etching another end of the multi-channel heterojunction layer to form a cathode region, the anode region comprising at least one set of anode finger grooves, any one set of anode finger grooves of the at least one set of anode finger grooves comprising a first anode finger groove, . . . , a m^{th} anode finger groove, . . . , and a n^{th} anode finger groove with different lengths in a direction from the substrate to the multi-channel heterojunction layer, where 1≤m≤n, n≥2, and both m and n are integers; and the m^{th} anode finger groove partially penetrating the multi-channel heterojunction layer to the m^{th} layer of heterojunction; and
disposing an anode in the anode region, and disposing a cathode in the cathode region, a first anode finger, . . . , a m^{th} anode finger, . . . , and a n^{th} anode finger being disposed in the first anode finger groove, . . . , the m^{th} anode finger groove, . . . , and the n^{th} anode finger groove, respectively, and the m^{th} anode finger partially penetrating the multi-channel heterojunction layer to the m^{th} layer of heterojunction.

15. The method for manufacturing the semiconductor structure according to claim 14, wherein a bottom surface of the m^{th} anode finger groove is located in any one of following positions in the m^{th} layer of heterojunction: in the channel layer, at an interface between the channel layer and the barrier layer, or in the barrier layer.

16. The method for manufacturing the semiconductor structure according to claim 14, wherein along a direction perpendicular to the direction from the substrate to the multi-channel heterojunction layer, a width of the m^{th} anode finger groove is less than a width of the (m−1)th anode finger groove, where 2≤m≤n, and both m and n are integers.

17. The method for manufacturing the semiconductor structure according to claim 14, further comprising:
disposing a plurality of first P-type regions at intervals located at an end of the multi-channel heterojunction layer, each of the plurality of first P-type regions extending towards the substrate from a surface of a side, away from the substrate, of the multi-channel heterojunction layer, and a bottom surface of at least one of the plurality of first P-type regions being located in the channel layer of the first layer of heterojunction.

18. The method for manufacturing the semiconductor structure according to claim 17, further comprising:
continuing to epitaxially form a healed second P-type layer on the plurality of first P-type regions.
